(19) United States
(12) Patent Application Publication
(10) Pub. No.: US 2024/0168067 A1
(43) Pub. Date: May 23, 2024

(54) SYSTEM AND PROCESS FOR REAL-TIME INPUT HARMONICS MONITORING

(71) Applicant: H&M Strategic Alliance, LLC, Montgomery, TX (US)

(72) Inventors: Joshua Hoffman, Montgomery, TX (US); Mohammed Shamsul Arefeen, Houston, TX (US)

(73) Assignee: H&M Strategic Alliance, LLC, Montgomery, TX (US)

(21) Appl. No.: 18/498,908

(22) Filed: Oct. 31, 2023

Related U.S. Application Data
(60) Provisional application No. 63/384,221, filed on Nov. 17, 2022.

(51) Int. Cl. G01R 19/25

(52) U.S. Cl. CPC G01R 19/2513; G01R 19/2509

(57) ABSTRACT

A system and process for real-time input harmonics monitoring that can be a permanent and autonomous system and process for real-time measuring, displaying, and monitoring electrical harmonic measurements in high-energy industrial applications. In particular, the system and process monitor harmonic interference in an input line current that originates from a utility supply and powers a variable speed drive supporting a load. The system and process include sensing a phase current in an input line current, converting the phase current to an analog voltage, translating the analog voltage to a digital output, calculating power quality measurements, applying algorithms with these power quality measurements, and generating a power quality report. The power quality report may be displayed to an operator, who may then use the real-time power quality information to execute targeted harmonics mitigation on a well and/or system.

### CROSS-REFERENCE TO RELATED APPLICATIONS

This application claims the benefit of U.S. Provisional Patent Application No. 63/384,221 filed on Nov. 17, 2022, and incorporates said provisional application by reference in its entirety into this document as if fully set out at this point.

### BACKGROUND OF THE INVENTION

### 1. Field of the Invention

This invention generally relates to a system and process for real-time input harmonics monitoring, and, more particularly, a permanent and autonomous system and process for real-time measuring, displaying, and monitoring electrical harmonic measurements in high-energy industrial applications.

### 2. Description of the Related Art

Harmonic distortion is the disruption in standard voltage patterns (sine wave) due to non-linear loads. All high-energy applications with variable speed drives (AC or DC) for an electric motor are exposed to harmonics. Disturbances from harmonics cause damage, inefficiencies, and failures, resulting in extensive energy consumption costs, equipment replacement, and operational intervention. Consequently, organizations operating high-energy industrial applications on variable frequency drives or switchboards all experience harmonic distortion at some level, which can negatively impact the long-term viability of electrical components, increase operations costs, and lower overall operational efficiencies. As a result, industries invest large amounts of capital within critical systems to identify and mitigate harmonic interference.

Harmonics monitoring of oil and gas production operations often requires large-scale pumping systems that can be deployed either at the surface or in the wellbore. Oil and gas production operations require high amounts of electricity, and in some cases, hundreds of wells may be operating on the same power grid. The current process for measuring the harmonics of production operations requires an individual well to be shut down, instrumented for harmonics measurement, turned back on, and the harmonics are measured over a period of time. Once the harmonics measurement is complete, the system is shut down again, the harmonics instrumentation is removed, and the system is turned back on for standard operations. This process is both time-intensive and capital-intensive, and the operational shutdowns negatively impact oil and gas producers' production targets and bottom line.

### SUMMARY OF THE INVENTION

The invention relates to a system and process to measure, display, and monitor electrical harmonic measurements in real time. The invention monitors the power quality of input line currents from a utility supply and relays the data to an operator, such that the operator is notified of harmonic interference and may deploy an appropriate power quality improvement effort. The system and process permit the operator to execute targeted, resource-efficient harmonics mitigation only where adaptive control is required.

Accordingly, it is an object of this invention to provide an improved system and process for real-time input harmonics monitoring.

Another object of this invention is to provide a permanent and autonomous system and process for real-time measuring, displaying, and monitoring electrical harmonic measurements in high-energy industrial applications.

A further object of this invention is to provide a system and process for measuring electrical harmonics in real time without disrupting operating oil and gas wells.

A further object of this invention is to provide a system and process for providing oil and gas operators with real-time utility supply harmonics information to minimize or mitigate potential damages.

A further object of this invention is to provide a system and process for deploying a real-time monitoring apparatus to monitor the existence and severity of harmonics to protect oil and gas wellbore systems with improved accuracy.

In general, in a first aspect, the invention relates to a system for performing real-time measurements of power quality of an input line current originating from a utility power supply. The system has a phase current sensor electrically coupled to the input line current originating from the power utility supply, and the phase current sensor is configured to determine a phase current from the input line current and convert the phase current to an analog voltage. The system also has an analog-to-digital converter electrically coupled to the input line current, and the analog-to-digital converter is configured to sample an analog voltage representing a phase current of the input line current and provides a digital output that corresponds to the analog voltage. In addition, the system has a real-time engine for performing algorithms for determining a plurality of power quality measurements from the digital output, and a microcontroller electrically coupled to the engine. The microcontroller is configured to calculate a power quality report from the plurality of power quality measurements, and a data display is configured to display a visual representation of the power quality report.

In one embodiment, the analog-to-digital converter samples the analog voltage from the phase current sensor to provide the digital output.

In one embodiment, the system also includes a voltage reduction circuitry electrically coupled to the analog-to-digital converter, wherein the voltage reduction circuitry measures a voltage directly from the input line current and converts the voltage to a lower voltage representative.

In one embodiment, the analog-to-digital converter samples the lower voltage representative from the voltage reduction circuitry to provide the digital output.

In one embodiment, the analog-to-digital converter samples both the lower voltage representative from the voltage reduction circuitry and the analog voltage from the phase current sensor to provide the digital output.

In one embodiment, the system also has a second phase current sensor electrically coupled to the analog-to-digital converter, wherein the second phase current sensor corresponds to a second input line current originating from the utility supply.

In one embodiment, the system also has a third phase current sensor electrically coupled to the analog-to-digital converter, wherein the third phase current sensor corresponds to a third input line current originating from the utility supply.

In one embodiment, the second phase current sensor senses a second phase current from the second input line current simultaneous with the sensing of the phase current from the input line current by the phase current sensor, wherein the third phase current sensor simultaneously senses a third phase current from the third input line current.

In one embodiment, the second phase current sensor converts the second phase current to a second analog voltage simultaneous with the conversion of the phase current to the analog voltage by the phase current sensor, wherein the third phase current sensor simultaneously converts the third phase current to a third analog voltage.

In one embodiment, the analog-to-digital converter simultaneously samples the analog voltage, the second analog voltage, and the third analog voltage to provide the digital output.

In one embodiment, the system also has a voltage reduction circuitry electrically coupled to the analog-to-digital converter, wherein the voltage reduction circuitry measures a voltage directly from the input line current and converts the voltage to a lower voltage representative, wherein the voltage reduction circuitry measures a second voltage directly from the input line current and converts the second voltage to a second lower voltage representative, and wherein the voltage reduction circuitry measures a third voltage directly from the input line current and converts the third voltage to a third lower voltage representative.

In one embodiment, the analog-to-digital converter samples the lower voltage representative, the second lower voltage representative, and the third lower voltage representative to provide the digital output.

In one embodiment, the analog-to-digital converter samples the lower voltage representative, the second lower voltage representative, and the third lower voltage representative from the voltage reduction circuitry, as well as the analog voltage, the second analog voltage, the third analog voltage of the phase current sensors to provide the digital output.

In one embodiment, the plurality of power quality measurements includes at least one of kWh, kW, power factor, peak current, and Root-Mean-Square (RMS) current.

In general, in a second aspect, the invention relates to a process for performing real-time measurements of power quality. The process includes the steps of sensing a phase current from an input line current originating from a utility supply; converting the phase current to an analog voltage; translating the analog voltage to a digital output; electronically calculating a plurality of power quality measurements from the digital output; electronically implementing algorithms with the plurality of power quality measurements to provide a power quality output; electronically generating a power quality report from the power quality output; and presenting a visual representation of the power quality report on a data display.

In one embodiment, the step of translating the analog voltage to the digital output includes translating the analog voltage to a lower voltage representative and translating the lower voltage representative to the digital output.

In one embodiment, the process also includes the steps of sensing a second phase current from a second input line current originating from the utility supply simultaneous with the step of sensing the phase current from the input line current sensing simultaneously a third phase current from a third input line current originating from the utility supply.

In one embodiment, the process also includes the steps of converting the second phase current to a second analog voltage simultaneous with the step of converting the phase current to the analog voltage and converting simultaneously the third phase current to a third analog voltage.

In one embodiment, the process also includes the steps of translating the second analog voltage to a second digital output simultaneous with the step of translating the analog voltage to a digital output and translating simultaneously the third analog voltage to a third digital output.

In one embodiment, the step of translating the analog voltage to the digital output further includes the steps of translating the analog voltage to a lower voltage representative and

translating the lower voltage representative to the digital output, wherein the step of translating the second analog voltage to the second digital output further comprises the step of translating the second analog voltage to a second lower voltage representative and translating the second lower voltage representative to the second digital output, and wherein the step of translating the third analog voltage to a third digital output further includes the steps of translating the third analog voltage to a third lower voltage representative and translating the third lower voltage representative to the third digital output.

In one embodiment, the process also includes the step of using the input line current to power a variable speed drive that supports a load.

### BRIEF DESCRIPTION OF THE DRAWINGS

The above and other objects and advantages of this invention may be more clearly seen when viewed in conjunction with the accompanying drawing wherein:

FIG. 1 is a block diagram of an example of a system for real-time input harmonics monitoring of a variable speed drive supporting a load in accordance with an illustrative embodiment of the invention disclosed herein.

FIG. 2 is a block diagram of an example of a system for real-time power quality measurement having a voltage reduction circuitry in accordance with an illustrative embodiment of the invention disclosed herein.

### DETAILED DESCRIPTION OF THE INVENTION

While this invention is susceptible to embodiment in many different forms, there are shown in the drawings and will herein be described in detail some specific embodiments of the invention. It should be understood, however, that the present disclosure is to be considered an exemplification of the principles of the invention and is not intended to limit the invention to the specific embodiments so described.

This invention generally relates to a real-time power quality measurement system and process for detecting harmonic distortions in an input line current fed from a utility supply source into a system with a variable speed drive (“VSD”) and load. The inventive system and process include sensors configured to electronically monitor input line currents from the utility source and execute a real-time algorithm to calculate the magnitude of each harmonic frequency component introduced from the utility supply source. The inventive system and process may be used to determine the desired level of mitigation needed at a particular well site and/or wellbore system without the need to deploy mitigation resources uniformly across the operator's entire system at the resource. The system and process provide for targeted mitigation that is more cost-effective and efficient than current methods. Further, the inventive system and process may be used with existing mitigation schemes installed in a well and/or at a system to quickly determine the effectiveness of these pre-existing schemes in addressing harmonics.

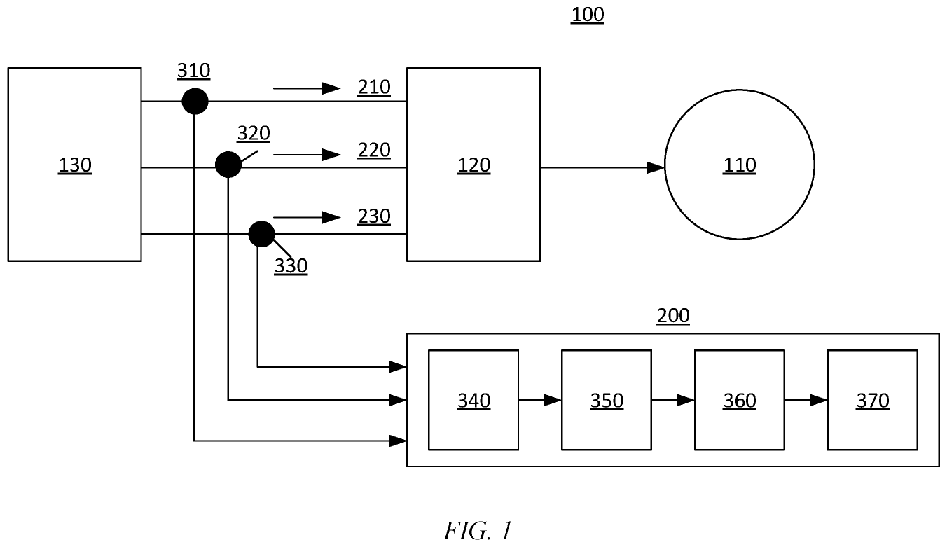

Referring to the figures of the drawings, wherein like numerals of reference designate like elements throughout the several views, and initially to FIG. 1, a real-time power quality measurement system 200 is used with an exemplary production system 100 that receives power from a utility supply 130. The production system 100 includes a load 110 supported by a VSD 120. While the inventive system 200 is illustrated in connection with an oil and gas production system 100, the inventive system and process 200 can be used with any VSD unit. Further, it is understood that the VSD units for the various embodiments of the system and process 200 could be configured to support various loads, including but not limited to, a process motor, an electrical submersible pump (ESP) system, or a rod-lift pumping system. The nature of the load and the extent of VSD operation in a particular system 100 affects the input power quality for that system 100.

The inventive system and process 200 can be configured for all types of utility power supply, including a single-phase utility supply. In the exemplary production system 100 illustrated in FIG. 1, the VSD 120 is powered by a three-phase utility supply 130. However, it should be noted that the nature of the utility supply for powering the VSD unit in different exemplary systems may vary depending on the area of service. A typical three-phase utility supply for North America is 480V and 60 Hz. In a theoretical 480V/60 Hz system without harmonic interference, the only frequency component is 60 Hz, and the magnitude of this fundamental component depends on the input line current magnitude. However, a VSD utilizing a diode-front end in a typical real-world system functions like a non-linear load, and as a result, the input line currents of a 480V/60 Hz utility supply have other harmonic components in addition to the fundamental component of 60 Hz.

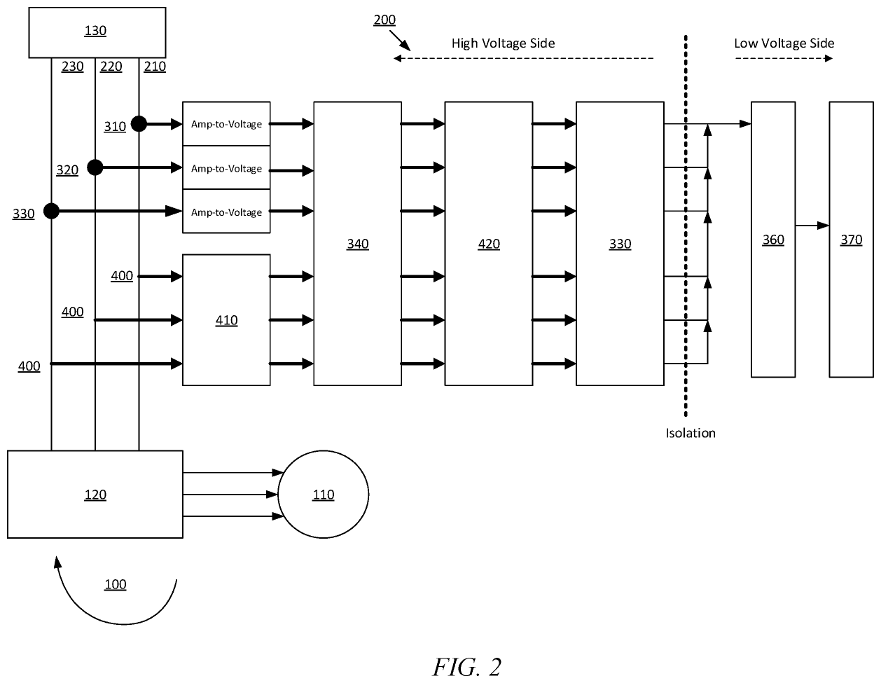

In the production system 100 illustrated in FIG. 1, input line currents 210, 220, and 230 from the utility supply 130 power the VSD 120. Each input line current 210, 220, and 230 is sampled by a corresponding phase current sensor 310, 320, and 330 (e.g., Rogowski coils). The phase current sensors 310, 320, and 330 sample the corresponding input line currents 210, 220, and 230 simultaneously to keep all measurements synchronized. The phase current sensors 310, 320, and 330 then convert the phase currents of each of the input line currents 210, 220, and 230 to an analog voltage proportionate to each phase current level. The converted analog voltages have a predetermined voltage range compatible with a microcontroller 360 of the inventive system and process 200. For example, FIG. 2 exemplifies an example of a voltage reduction circuitry that converts the phase current to the converted analog voltage by the phase current sensors 310, 320, and 330.

As shown in FIG. 1, the inventive system 200 includes an analog-to-digital converter 340 electrically coupled to the phase current sensors 310, 320, and 330. The analog-to-digital converter 340 is configured to sample the analog voltages representing the phase currents of input line currents 210, 220, and 230. The analog-to-digital converter 340 may sample all analog voltages simultaneously to keep the measurements synchronized. The analog-to-digital converter 340 may provide a digital output corresponding to the analog voltages.

As shown in FIG. 2, the inventive system 200 may also have the voltage reduction circuitry 410 electrically coupled to the analog-to-digital converter 340, wherein the voltage reduction circuitry 410 has a voltage connection 400 corresponding to each input line current 210, 220, and 230. In this exemplary system 200, the phase voltage of input line currents 210, 220, and 230 may be directly and simultaneously measured by passing the voltages through the voltage reduction circuitry 410. The voltage reduction circuitry 410 creates a low voltage corresponding to the high phase voltage of each input line current 210, 220, and 230. By performing voltage reduction, the circuitry 410 eliminates the need for a control side of the system 200 to be configured for high-voltage operations. In various embodiments, the voltage reduction circuitry 410 may be used either in place of the phase current sensors 310, 320, and 330 in the system 200 or in conjunction with the sensors 310, 320, and 330, as shown in the exemplary embodiment of FIG. 2. When the voltage reduction circuitry 410 is utilized with the system 200, the analog-to-digital converter 340 may sample the low voltage for input line currents 210, 220, and 230 to provide a digital output. In other embodiments, the analog-to-digital converter 340 may instead provide a digital output that corresponds to both the low voltage of the voltage reduction circuitry 410 and the analog voltages of the phase current sensors 310, 320, and 330.

The exemplary system 200 illustrated in FIG. 2 further includes the real-time engine 350 for calculating power quality that is electrically coupled to the analog-to-digital converter 340. The engine 350 utilizes the digital output from the analog-to-digital converter 340 to calculate the power quality of the input line currents 210, 220, and 230 by performing various power quality measurements. These power quality measurements include, but are not limited to, measurements for kWh, kW, power factor, peak current, and Root-Mean-Square (RMS) current. These power quality measurements are used by the real-time engine 350 for implementing Fast Fourier Transform algorithms to calculate individual harmonics corresponding to the input line currents 210, 220, and 230. From these calculations, the real-time engine 350 provides a power quality output to the microcontroller 360, which uses the power quality output from engine 350 to create a power quality report that denotes whether any harmonic interferences have been detected from the input line currents 210, 220, or 230. The microcontroller 360 subsequently provides the power quality report to a data display 370, which provides a visual representation of the power quality report to a system operator. The system operator can utilize the power quality report to quickly identify any real-time harmonics issues in the input line currents 210, 220, or 230 that power a specific well and/or production system. The power quality report may further inform the system operator of the extent of harmonics mitigation needed to protect the impacted well and/or production system. In various embodiments, the power quality report may provide specific information to the system operator on power quality aspects such as voltage distortion, supply unbalance, and sudden load variation. The data display 370 may further present operational alarms to the operator when certain harmonic conditions are detected.

The real-time power quality measurement system 200 can be mounted on a skid or mobile so that it can be easily transported and deployed with different wells and/or systems. In alternative embodiments, the system 200 may be permanently installed at a well, a production system, or a resource.

It is understood that in some embodiments, data from the system 200 is continuously and autonomously supplied to the operator. In other embodiments, data from the system 200 is relayed to the operator at a customized sample rate at certain intervals, which may be pre-set and altered by the operator. In other further embodiments, the system 200 provides data to the operator upon demand.

If programmable logic is used, such logic may execute on a commercially available processing platform or a special-purpose device. One of ordinary skill in the art may appreciate that embodiments of the disclosed subject matter can be practiced with various computer system configurations, including multi-core multi-processor systems, minicomputers, mainframe computers, computers linked or clustered with distributed functions, as well as pervasive or miniature computers that may be embedded into virtually any device.

Moreover, the system and process disclosed herein can be implemented using a “smart application”-type software, allowing the system and process to be operated remotely by a tablet or smartphone. For example, the system and process may be implemented in a computer system using hardware, software, firmware, tangible computer-readable media having instructions stored thereon, or a combination thereof and may be implemented in one or more computer systems or other processing systems.

For instance, at least one processor device and a memory may be used to implement the above-described embodiments. A processor device may be a single processor, a plurality of processors, or combinations thereof. Processor devices may have one or more processor “cores.”

Various embodiments of the inventions may be implemented in terms of this example computer system. After reading this description, it will become apparent to a person skilled in the relevant art how to implement one or more of the inventions using other computer systems and/or computer architectures. Although operations may be described as a sequential process, some of the operations may be performed in parallel, concurrently, and/or in a distributed environment and with program code stored locally or remotely for access by single or multi-processor machines. In addition, in some embodiments, the order of operations may be rearranged without departing from the spirit of the disclosed subject matter.

The processor device may be a special-purpose or a general-purpose processor device or maybe a cloud service wherein the processor device may reside in the cloud. As will be appreciated by persons skilled in the relevant art, the processor device may also be a single processor in a multi-core/multi-processor system, such system operating alone or in a cluster of computing devices operating in a cluster or server farm. The processor device is connected to a communication infrastructure, for example, a bus, message queue, network, or multi-core message-passing scheme.

The computer system also includes a main memory, for example, random access memory (RAM), and may also include a secondary memory. The secondary memory may include, for example, a hard disk drive or a removable storage drive. The removable storage drive may include a floppy disk drive, a magnetic tape drive, an optical disk drive, a flash memory, a Universal Serial Bus (USB) drive, or the like. The removable storage drive reads from and/or writes to a removable storage unit in a well-known manner. The removable storage unit may include a floppy disk, magnetic tape, optical disk, etc., which is read by and written to by the removable storage drive. As will be appreciated by persons skilled in the relevant art, the removable storage unit includes a computer usable storage medium having stored therein computer software and/or data.

The computer system (optionally) includes a display interface (which can include input and output devices such as keyboards, mice, etc.) that forwards graphics, text, and other data from communication infrastructure (or from a frame buffer not shown) for display on a display unit.

In alternative implementations, the secondary memory may include other similar means for allowing computer programs or other instructions to be loaded into the computer system. Such means may include, for example, the removable storage unit and an interface. Examples of such means may include a program cartridge and cartridge interface (such as that found in video game devices), a removable memory chip (such as an EPROM, PROM, or Flash memory) and associated socket, and other removable storage units and interfaces which allow software and data to be transferred from the removable storage unit to computer system.

The computer system may also include a communication interface. The communication interface allows software and data to be transferred between the computer system and external devices. The communication interface may include a modem, a network interface (such as an Ethernet card), a communication port, a PCMCIA slot, and card, or the like. Software and data transferred via the communication interface may be in the form of signals, which may be electronic, electromagnetic, optical, or other signals capable of being received by the communication interface. These signals may be provided to the communication interface via a communication path. Communication path carries signals, such as over a network in a distributed computing environment, for example, an intranet or the Internet, and may be implemented using wire or cable, fiber optics, a phone line, a cellular phone link, an RF link, or other communication channels.

In this document, the terms “computer program medium” and “computer usable medium” are used to generally refer to media such as removable storage unit, removable storage unit, and a hard disk installed in the hard disk drive. The computer program medium and computer usable medium may also refer to memories, such as main memory and secondary memory, which may be memory semiconductors (e.g., DRAMs, etc.) or cloud computing.

Computer programs (also called computer control logic) are stored in the main memory and/or the secondary memory. The computer programs may also be received via the communication interface. Such computer programs, when executed, enable the computer system to implement the embodiments as discussed herein, including but not limited to machine learning and advanced artificial intelligence. In particular, the computer programs, when executed, enable the processor device to implement the processes of the embodiments discussed here. Accordingly, such computer programs represent controllers of the computer system. Where the embodiments are implemented using software, the software may be stored in a computer program product and loaded into the computer system using the removable storage drive, the interface, the hard disk drive, or the communication interface.

Moreover, embodiments of the disclosure may be practiced with other computer system configurations, including hand-held devices, multi-processor systems, microprocessor-based or programmable consumer electronics, minicomputers, mainframe computers, and the like. Embodiments of the disclosure may also be practiced in distributed computing environments where tasks are performed by remote processing devices that are linked through a communications network. In a distributed computing environment, program modules may be located in both local and remote memory storage devices.

Embodiments of the inventions also may be directed to computer program products comprising software stored on any computer useable medium. Such software, when executed in one or more data processing devices, causes a data processing device(s) to operate as described herein. Embodiments of the inventions may employ any computer-useable or readable medium. Examples of computer useable mediums include, but are not limited to, primary storage devices (e.g., any type of random access memory), secondary storage devices (e.g., hard drives, floppy disks, CD ROMS, ZIP disks, tapes, magnetic storage devices, and optical storage devices, MEMS, nanotechnological storage device, etc.).

Where applicable, although state diagrams, flow diagrams or both may be used to describe embodiments, the invention is not limited to those diagrams or to the corresponding descriptions. For example, flow need not move through each illustrated box or state, or in exactly the same order as illustrated and described.

Processes of the instant disclosure may be implemented by performing or completing manually, automatically, or a combination thereof, selected steps or tasks.

The term “process” may refer to manners, means, techniques and procedures for accomplishing a given task including, but not limited to, those manners, means, techniques and procedures either known to, or readily developed from known manners, means, techniques and procedures by practitioners of the art to which the invention belongs.

It should be noted that where reference is made herein to a process comprising two or more defined steps, the defined steps can be carried out in any order or simultaneously (except where context excludes that possibility), and the process can also include one or more other steps which are carried out before any of the defined steps, between two of the defined steps, or after all of the defined steps (except where context excludes that possibility).

The above description is given by way of example only, and various modifications may be made by those skilled in the art. The above specification, examples, and data provide a complete description of the structure and use of exemplary embodiments. Although various embodiments have been described above with a certain degree of particularity or with reference to one or more individual embodiments, those skilled in the art could make numerous alterations to the disclosed embodiments without departing from the scope of this specification.

What is claimed is:

1. A system for performing real-time measurements of power quality of an input line current originating from a utility power supply, said system comprising:
a phase current sensor electrically coupled to the input line current originating from the power utility supply, the phase current sensor configured to determine a phase current from the input line current and convert the phase current to an analog voltage;
an analog-to-digital converter electrically coupled to the input line current, the analog-to-digital converter configured to sample an analog voltage representing a phase current of the input line current and provides a digital output that corresponds to the analog voltage;
a real-time engine for performing algorithms for determining a plurality of power quality measurements from the digital output;
a microcontroller electrically coupled to the engine, the microcontroller configured to calculate a power quality report from the plurality of power quality measurements; and
a data display configured to display a visual representation of the power quality report.

2. The system of claim 1, wherein the analog-to-digital converter samples the analog voltage from the phase current sensor to provide the digital output.

3. The system of claim 1 further comprising a voltage reduction circuitry electrically coupled to the analog-to-digital converter, wherein the voltage reduction circuitry measures a voltage directly from the input line current and converts the voltage to a lower voltage representative.

4. The system of claim 3, wherein the analog-to-digital converter samples the lower voltage representative from the voltage reduction circuitry to provide the digital output.

5. The system of claim 3, wherein the analog-to-digital converter samples both the lower voltage representative from the voltage reduction circuitry and the analog voltage from the phase current sensor to provide the digital output.

6. The system of claim 1 further comprising:
a second phase current sensor electrically coupled to the analog-to-digital converter, wherein the second phase current sensor corresponds to a second input line current originating from the utility supply; and
a third phase current sensor electrically coupled to the analog-to-digital converter, wherein the third phase current sensor corresponds to a third input line current originating from the utility supply.

7. The system of claim 6, wherein the second phase current sensor senses a second phase current from the second input line current simultaneous with the sensing of the phase current from the input line current by the phase current sensor; and wherein the third phase current sensor simultaneously senses a third phase current from the third input line current.

8. The system of claim 7, wherein the second phase current sensor converts the second phase current to a second analog voltage simultaneous with the conversion of the phase current to the analog voltage by the phase current sensor; and wherein the third phase current sensor simultaneously converts the third phase current to a third analog voltage.

9. The system of claim 8, wherein the analog-to-digital converter simultaneously samples the analog voltage, the second analog voltage, and the third analog voltage to provide the digital output.

10. The system of claim 8 further comprising a voltage reduction circuitry electrically coupled to the analog-to-digital converter,
wherein the voltage reduction circuitry measures a voltage directly from the input line current and converts the voltage to a lower voltage representative;
wherein the voltage reduction circuitry measures a second voltage directly from the input line current and converts the second voltage to a second lower voltage representative; and
wherein the voltage reduction circuitry measures a third voltage directly from the input line current and converts the third voltage to a third lower voltage representative.

11. The system of claim 10, wherein the analog-to-digital converter samples the lower voltage representative, the second lower voltage representative, and the third lower voltage representative to provide the digital output.

12. The system of claim 10, wherein the analog-to-digital converter samples the lower voltage representative, the second lower voltage representative, and the third lower voltage representative from the voltage reduction circuitry, as well as the analog voltage, the second analog voltage, the third analog voltage of the phase current sensors to provide the digital output.

13. The system of claim 1, wherein the plurality of power quality measurements includes at least one of kWh, kW, power factor, peak current, and Root-Mean-Square (RMS) current.

14. A process for performing real-time measurements of power quality, said process comprising the steps of:
a. sensing a phase current from an input line current originating from a utility supply;
b. converting the phase current to an analog voltage;
c. translating the analog voltage to a digital output;
d. electronically calculating a plurality of power quality measurements from the digital output;
e. electronically implementing algorithms with the plurality of power quality measurements to provide a power quality output;
f. electronically generating a power quality report from the power quality output; and
g. presenting a visual representation of the power quality report on a data display.

15. The process of claim 14, wherein said step of translating the analog voltage to the digital output further comprises the steps of:
translating the analog voltage to a lower voltage representative; and
translating the lower voltage representative to the digital output.

16. The process of claim 15 further comprising the steps of:
sensing a second phase current from a second input line current originating from the utility supply simultaneous with the step of sensing the phase current from the input line current; and
sensing simultaneously a third phase current from a third input line current originating from the utility supply.

17. The process of claim 16 further comprising the steps of:
converting the second phase current to a second analog voltage simultaneous with the step of converting the phase current to the analog voltage; and
converting simultaneously the third phase current to a third analog voltage.

18. The process of claim 17 further comprising the steps of:
translating the second analog voltage to a second digital output simultaneous with the step of translating the analog voltage to a digital output; and
translating simultaneously the third analog voltage to a third digital output.

19. The process of claim 18
wherein the step of translating the analog voltage to the digital output further comprises the steps of:
translating the analog voltage to a lower voltage representative; and
translating the lower voltage representative to the digital output;
wherein the step of translating the second analog voltage to the second digital output further comprises the steps of:
translating the second analog voltage to a second lower voltage representative; and
translating the second lower voltage representative to the second digital output; and
wherein the step of translating the third analog voltage to a third digital output further comprises the steps of:
translating the third analog voltage to a third lower voltage representative; and
translating the third lower voltage representative to the third digital output.

20. The process of claim 19 further comprising the step of using the input line current to power a variable speed drive that supports a load.
